(19) United States
(12) Patent Application Publication
(10) Pub. No.: US 2026/0005015 A1
(43) Pub. Date: Jan. 1, 2026

(54) METHODS OF DEPOSITING SILICON-CONTAINING FILMS FOR SEMICONDUCTOR DEVICES

(71) Applicant: Applied Materials, Inc., Santa Clara, CA (US)

(72) Inventor: Ning Li, San Jose, CA (US)

(73) Assignee: Applied Materials, Inc., Santa Clara, CA (US)

(21) Appl. No.: 18/756,396

(22) Filed: Jun. 27, 2024

(51) Int. Cl. H01L 21/02

(52) U.S. Cl. CPC H01L 21/02274; H01L 21/0217; H01L 21/0228

(57) ABSTRACT

Methods of depositing silicon-containing films by plasma-enhanced atomic layer deposition (PEALD) are disclosed. Exemplary methods include exposing a substrate in a processing system to a silicon-containing precursor; exposing the substrate to a nitrogen-containing reactant; exposing the substrate to a first plasma including one or more of nitrogen (N₂) or hydrogen (H₂), and one or more of argon (Ar) or helium (He); and exposing the substrate to a second plasma including one or more of nitrogen (N₂), argon (Ar), helium (He), oxygen (O₂), nitrous oxide (N₂O), or carbon dioxide (CO₂).

### TECHNICAL FIELD

Embodiments of the disclosure generally relate to the field of semiconductor device manufacturing. More particularly, embodiments of the disclosure are directed to methods of depositing silicon-containing films by plasma-enhanced atomic layer deposition (PEALD).

### BACKGROUND

Silicon-containing films, such as, for example, silicon nitride (SiN), silicon oxide (SiO), silicon carbonitride (SiCN), silicon oxycarbide (SiOC), and silicon carboxynitride (SiCON) films have attractive dielectric material properties. These films have been proposed and tested for applications from front-end of line (FEOL) to back-end of line (BEOL) processes and parts of semiconductor devices and microelectronic devices. Generally, FEOL refers to the first portion of integrated circuit fabrication, including transistor fabrication, middle of line (MOL) connects the transistor and interconnect parts of a chip using a series of contact structures, and back-end of line (BEOL) refers to a series of process steps after transistor fabrication through completion of a semiconductor wafer.

Low temperature, e.g., less than or equal to 600° C., atomic layer deposition (ALD) of silicon-containing films is used in many semiconductor applications. Without intending to be bound by any particular theory, it is thought that many of these films are deposited by PEALD due to poor film quality when deposited by low temperature thermal processes, e.g., thermal ALD processes. In particular, it has been found that silicon-containing films with good conformality deposited by thermal ALD processes have poor film quality at temperatures less than or equal to 600° C.

PEALD film quality varies based on the surface (e.g., substrate) on which the film is deposited. In particular, it has been found that PEALD film quality varies based on the geometry of the substrate, and areas that are harder to treat with plasma species may receive less plasma treatment and have poorer film quality. PEALD may also utilize a single plasma exposure to perform both a reaction step between a silicon-containing precursor and a reactant to form a film, and a densification step.

Unfortunately, the combination of the reaction step and the densification step leads to the incorporation of reaction byproducts into the films as impurities, thereby causing lower film quality. For example, current PEALD approaches, e.g., (1) exposure to silicon-containing precursor, purge, exposure to thermal ammonia (NH₃), followed by nitrogen (N₂) plasma, or (2) exposure to silicon-containing precursor, purge, exposure to ammonia (NH₃) plasma, and purge, to form a silicon nitride (SiN) film, which each include a single plasma exposure, may independently produce films of poor quality.

Accordingly, there is a need for PEALD processes for depositing silicon-containing films having improved film quality.

### SUMMARY

One or more embodiments of the disclosure are directed to a method of depositing a silicon-containing film. The method comprises exposing a substrate in a processing system to a silicon-containing precursor; exposing the substrate to a nitrogen-containing reactant; exposing the substrate to a first plasma including one or more of nitrogen (N₂) or hydrogen (H₂), and one or more of argon (Ar) or helium (He); and exposing the substrate to a second plasma including one or more of nitrogen (N₂), argon (Ar), helium (He), oxygen (O₂), nitrous oxide (N₂O), or carbon dioxide (CO₂).

Additional embodiments of the disclosure are directed to a method of deposition a silicon-containing film. The method comprises exposing a substrate in a processing system to a silicon-containing precursor; exposing the substrate to ammonia (NH₃); exposing the substrate to a first plasma including nitrogen (N₂) and argon (Ar); and exposing the substrate to a second plasma including nitrogen (N₂) and helium (He), wherein the method comprises a plasma-enhanced atomic layer deposition (PEALD) process, and exposing the substrate to the silicon-containing precursor and the ammonia (NH₃) is performed without the use of plasma.

Further embodiments of the disclosure are directed to a method of deposition a silicon-containing film. The method comprises exposing a substrate in a processing system to a silicon-containing precursor; exposing the substrate to ethylenediamine; exposing the substrate to a first plasma including hydrogen (H₂) and argon (Ar); and exposing the substrate to a second plasma including one or more of oxygen (O₂), nitrous oxide (N₂O), or carbon dioxide (CO₂), wherein the method comprises a plasma-enhanced atomic layer deposition (PEALD) process, and exposing the substrate to the silicon-containing precursor and the ethylenediamine is performed without the use of plasma.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of the present disclosure and are therefore not to be considered limiting of its scope, for the disclosure may admit to other equally effective embodiments.

FIG. 1 illustrates a process flow diagram of a method of depositing a silicon-containing film according to one or more embodiments of the disclosure;

FIG. 2A illustrates a cross-sectional schematic view of a substrate according to one or more embodiments of the disclosure;

FIG. 2B illustrates a cross-sectional schematic view of a substrate according to one or more embodiments of the disclosure;

FIG. 2C illustrates a cross-sectional schematic view of a substrate according to one or more embodiments of the disclosure; and

FIG. 2D illustrates a cross-sectional schematic view of a substrate according to one or more embodiments of the disclosure.

To facilitate understanding, identical reference numerals have been used, where possible, to designate identical elements that are common to the Figures. It is contemplated that elements and features of one embodiment may be beneficially incorporated in other embodiments without further recitation.

### DETAILED DESCRIPTION

Before describing several exemplary embodiments of the disclosure, it is to be understood that the disclosure is not limited to the details of construction or process steps set forth in the following description. The disclosure is capable of other embodiments and of being practiced or being carried out in various ways.

The term “about” as used herein means approximately or nearly and in the context of a numerical value or range set forth means a variation of ±15% or less, of the numerical value. For example, a value differing by ±14%, ±10%, ±5%, ±2%, ±1%, ±0.5%, or ±0.1% would satisfy the definition of “about.”

Spatially relative terms, such as “beneath,” “below,” “lower,” “above,” “upper” and the like, may be used herein for ease of description to describe one element or feature's relationship to another element(s) or feature(s) as illustrated in the Figures. It will be understood that the spatially relative terms are intended to encompass different orientations of a device in use or operation in addition to the orientation depicted in the Figures. For example, if the device in the Figures is turned over, elements described as “below” or “beneath” other elements or features would then be oriented “above” the other elements or features. Thus, the exemplary term “below” may encompass both an orientation of above and below. The device may be otherwise oriented (rotated 90 degrees or at other orientations) and the spatially relative descriptors used herein interpreted accordingly.

The use of the terms “a” and “an” and “the” and similar referents in the context of describing the materials and methods discussed herein (especially in the context of the following claims) are to be construed to cover both the singular and the plural, unless otherwise indicated herein or clearly contradicted by context. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the materials and methods and does not pose a limitation on the scope unless otherwise claimed. No language in the specification should be construed as indicating any non-claimed element as essential to the practice of the disclosed materials and methods.

Reference throughout this specification to “one embodiment,” “some embodiments,” “certain embodiments,” “one or more embodiments,” or “an embodiment” means that a particular feature, structure, material, or characteristic described in connection with the embodiment is included in at least one embodiment of the disclosure. Thus, the appearances of the phrases such as “in one embodiment,” “in some embodiments,” “in certain embodiments,” “in one or more embodiments,” or “in an embodiment” in various places throughout this specification are not necessarily referring to the same embodiment of the disclosure. Furthermore, the particular features, structures, materials, or characteristics may be combined in any suitable manner in one or more embodiments.

As used in this specification and the appended claims, the term “substrate” or “wafer” refers to a surface, or portion of a surface, upon which a process acts. It will also be understood by those skilled in the art that reference to a substrate can refer to only a portion of the substrate, unless the context clearly indicates otherwise. Additionally, reference to depositing on a substrate can mean both a bare substrate and a substrate with one or more films or features deposited or formed thereon.

A “substrate” as used herein, refers to any substrate or material surface formed on a substrate upon which film processing is performed during a fabrication process. For example, a substrate surface on which processing can be performed include materials such as silicon, silicon oxide, strained silicon, silicon on insulator (SOI), carbon doped silicon oxides, amorphous silicon, doped silicon, germanium, gallium arsenide, and any other materials such as a metallic material, metal nitrides, metal alloys, and other conductive materials, depending on the application. Substrates include, without limitation, semiconductor wafers. Substrates may be exposed to a pretreatment process to polish, etch, reduce, oxidize, hydroxylate, anneal and/or bake the substrate surface. In addition to film processing directly on the surface of the substrate itself, in the present disclosure, any of the film processing steps disclosed may also be performed on an under-layer formed on the substrate as disclosed in more detail below, and the term “substrate surface” is intended to include such under-layer as the context indicates. Thus, for example, where a film/layer or partial film/layer has been deposited onto a substrate surface, the exposed surface of the newly deposited film/layer becomes the substrate surface.

The substrate may have one or more features formed therein, one or more layers formed thereon, and combinations thereof. The shape of the feature can be any suitable shape including, but not limited to, trenches, holes and vias (circular or polygonal). As used in this regard, the term “feature” refers to any intentional surface irregularity. Suitable examples of features include but are not limited to trenches, which have a top, two sidewalls and a bottom extending into the substrate, vias which have one or more sidewalls extending into the substrate to a bottom, and slot vias.

The features described herein can extend vertically into the substrate and/or laterally within the substrate. Unless specifically indicated otherwise, the features described herein are not limited to either of a vertically extending feature or a laterally extending feature. In one or more embodiments, the substrate comprises at least one vertically extending feature. In one or more embodiments, the substrate comprises at least one laterally extending feature. In one or more embodiments, the substrate comprises at least one vertically extending feature and at least one laterally extending feature.

The features described herein can have any suitable aspect ratio (ratio of the depth of the feature to the width of the feature). In one or more embodiments, the aspect ratio of the features described herein is greater than or equal to about 1:1, 2:1, 5:1, 10:1, 15:1, 20:1, 25:1, 30:1, 35:1, 40:1, 50:1, 60:1, 70:1, 80:1, 90:1, 100:1, 125:1, or 150:1. In one or more embodiments, the aspect ratio of the features described herein is in a range of from 1:1 to 150:1.

The term “on” indicates that there is direct contact between elements. The term “directly on” indicates that there is direct contact between elements with no intervening elements.

As used herein, the term “in situ” refers to processes that are all performed in the same processing chamber or within different processing chambers that are connected as part of an integrated processing system, such that each of the processes are performed without an intervening vacuum break. As used herein, the term “ex situ” refers to processes that are performed in at least two different processing chambers such that one or more of the processes are performed with an intervening vacuum break. In some embodiments, processes are performed without breaking vacuum or without exposure to ambient air.

As used in this specification and the appended claims, the terms “precursor”, “reactant”, “reactive gas” and the like are used interchangeably to refer to any gaseous species that can react with the substrate surface.

“Atomic layer deposition” or “cyclical deposition” as used herein refers to the sequential exposure of two or more reactive compounds to deposit a layer of material on a substrate surface. The substrate, or portion of the substrate, is exposed separately to the two or more reactive compounds which are introduced into a reaction zone of a processing chamber. In a time-domain ALD process, exposure to each reactive compound is separated by a time delay to allow each compound to adhere and/or react on the substrate surface and then be purged from the processing chamber. These reactive compounds are said to be exposed to the substrate sequentially. The skilled artisan will appreciate that a “time-domain ALD process” can also be referred to as a “temporal ALD process.”

In a spatial ALD process, different portions of the substrate surface, or material on the substrate surface, are exposed simultaneously to the two or more reactive compounds so that any given point on the substrate is substantially not exposed to more than one reactive compound simultaneously. As used in this specification and the appended claims, the term “substantially” used in this respect means, as will be understood by those skilled in the art, that there is the possibility that a small portion of the substrate may be exposed to multiple reactive gases simultaneously due to diffusion, and that the simultaneous exposure is unintended.

In one aspect of a time-domain ALD process, a first reactive gas (i.e., a first precursor or compound A) is pulsed into the reaction zone followed by a first time delay. Next, a second precursor or compound B is pulsed into the reaction zone followed by a second delay. During each time delay, a purge gas, such as argon, is introduced into the processing chamber to purge the reaction zone or otherwise remove any residual reactive compound or reaction by-products from the reaction zone. Alternatively, the purge gas may flow continuously throughout the deposition process so that only the purge gas flows during the time delay between pulses of reactive compounds. The reactive compounds are alternatively pulsed until a desired film or film thickness is formed on the substrate surface. In either scenario, the ALD process of pulsing compound A, purge gas, compound B and purge gas is a cycle. A cycle can start with either compound A or compound B and continue the respective order of the cycle until achieving a film with the predetermined thickness.

In an embodiment of a spatial ALD process, a first reactive gas and second reactive gas are delivered simultaneously to the reaction zone but are separated by an inert gas curtain and/or a vacuum curtain. The substrate is moved relative to the gas delivery apparatus so that any given point on the substrate is exposed to the first reactive gas and the second reactive gas.

As used herein, the term “thermal process(es)” refers to a deposition technique that does not involve the use of plasma. As used herein, the term “plasma” refers to a composition have ionically charged species and uncharged neutral and radical species. As used herein, a “radical-rich plasma” comprises greater than 50% radical species.

One or more of the layers deposited on the substrate are continuous. As used herein, the term “continuous” refers to a layer that covers an entire exposed surface without gaps or bare spots that reveal material underlying the deposited layer. A continuous layer may have gaps or bare spots with a surface area less than about 15% or less than about 10% of the total surface area of the layer.

One or more layers deposited on the substrate by atomic layer deposition (ALD) or plasma-enhanced atomic layer deposition (PEALD) are conformal. As used herein, as will be understood by the skilled artisan, a layer which is “conformal” or “conformally deposited” refers to a layer where the thickness is about the same throughout. A layer/film which is conformal varies in thickness by less than or equal to about 5%, 2%, 1% or 0.5%.

Plasma-enhanced atomic layer deposition (PEALD) methods add a plasma exposure to traditional ALD methods. In some PEALD methods, a nitrogen source is provided as the plasma. The primary benefit of PEALD methods is the relatively low substrate temperature, e.g., less than or equal to 600° C., during processing.

Embodiments of the disclosure are directed to methods of depositing silicon-containing films by plasma-enhanced atomic layer deposition (PEALD). The skilled artisan will recognize that the use of a molecular formula, such as, for example, silicon nitride (SiₓN_{y}) does not imply specific stoichiometric relation between the elements but merely the identity of the major components of the film. In some embodiments, the major composition of the specified film (i.e., the sum of the atomic percent of the specified atoms) is greater than or equal to about 95%, 98%, 99%, 99.5%, or 99.9% of the film, on an atomic basis. In one or more embodiments, as an example, the silicon-containing film comprises silicon nitride (SiₓN_{y}) in the form of Si₃N₄.

Some embodiments advantageously provide the ability to control the composition of silicon-containing films in accordance with the methods described herein. Some embodiments advantageously provide methods of depositing silicon-containing films having improved film quality on a substrate comprising at least one feature, e.g., at least one vertically extending feature and/or at least one laterally extending feature. Some embodiments advantageously provide methods of depositing improved quality silicon-containing films that are useful for FEOL and BEOL processes and parts.

There are multiple metrics used to measure the silicon-containing film quality. One of the most common metrics used to measure the silicon-containing film quality is the wet etch rate of the deposited film under dilute hydrofluoric (HF) acid etch solution, such as dilute HF 100:1. Embodiments of the disclosure advantageously provide silicon-containing films that have a reduced etch amount in Angstroms (Å) using dilute HF 100:1, which represents an improved wet etch rate, compared to current PEALD approaches.

One or more embodiments are directed to methods of depositing silicon-containing films in high aspect ratio structures, e.g., in memory devices or logic devices (at less than 10 nm technology nodes), including, but not limited to, NAND, 3D-NAND, dynamic random-access memory (DRAM) cells, 3D DRAM, Fin field effect transistors (FinFET), gate-all-around (GAA) transistors, and the like.

As used herein, a “high aspect ratio” structure has an aspect ratio greater than or equal to about 20:1, such as, for example, in a range of from 50:1 to 150:1. In some embodiments, the silicon-containing film is conformally deposited on the high aspect ratio feature.

The embodiments of the disclosure are described by way of the Figures, which illustrate processes, substrates, and apparatuses in accordance with one or more embodiments of the disclosure. The processes and resulting substrates shown are merely illustrative of the disclosed processes, and the skilled artisan will recognize that the disclosed processes are not limited to the illustrated applications.

In the following description, numerous specific details are set forth in order to provide a thorough understanding of the embodiments of the disclosure. It will be apparent to one skilled in the art that embodiments may be practiced without these specific details. In other instances, well-known aspects are not described in detail in order to not unnecessarily obscure embodiments. Furthermore, it is to be understood that the various embodiments shown in the accompanying drawings are illustrative representations and are not necessarily drawn to scale.

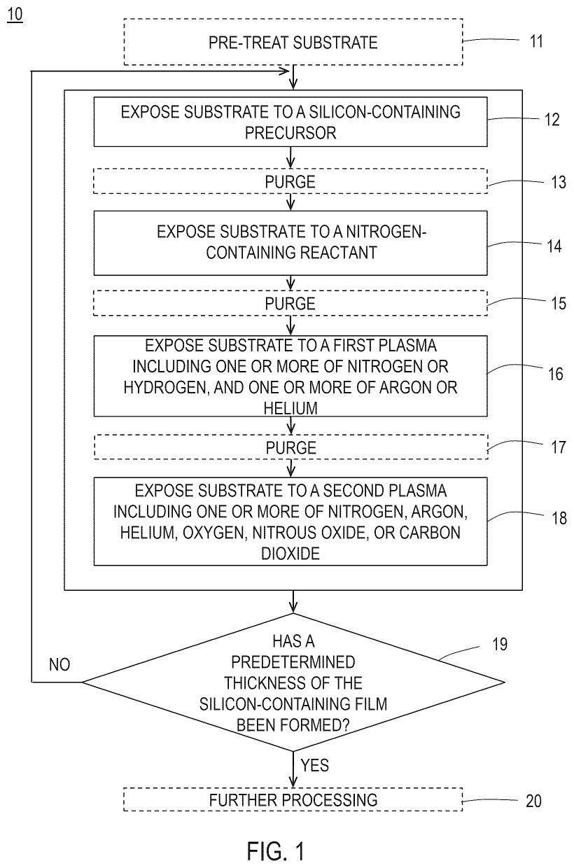

FIG. 1 illustrates a process flow diagram of a method 10 of depositing a silicon-containing film 200 on a substrate 102. The method 10 begins by optionally pre-treating the substrate 102 (operation 11). The pre-treatment can be any suitable pre-treatment known to the skilled artisan. Suitable pre-treatments include, but are not limited to, pre-heating, cleaning, soaking, or native oxide removal, as examples.

The method 10 of one or more embodiments comprises depositing the silicon-containing film 200 by PEALD. In one or more embodiments, the method 10 comprises exposing the substrate 102 to a silicon-containing precursor (operation 12); optionally purging the substrate 102 (operation 13); exposing the substrate 102 to a nitrogen-containing reactant (operation 14); optionally purging the substrate 102 (operation 15); exposing the substrate 102 to a first plasma including one or more of nitrogen (N₂) or hydrogen (H₂), and one or more of argon (Ar) or helium (He) (operation 16); optionally purging the substrate 102 (operation 17); and exposing the substrate 102 to a second plasma including one or more of nitrogen (N₂), argon (Ar), helium (He), oxygen (O₂), nitrous oxide (N₂O), or carbon dioxide (CO₂) (operation 18). In one or more embodiments of FIG. 1, the dashed lines are used to denote that the stated operation is optional.

The use of ordinals such as “first” and “second” to describe the specific plasmas, e.g., the first plasma and the second plasma, does not necessarily imply an order of formation, unless the context specifically indicates otherwise. A substrate may be exposed to a “second” plasma before the substrate is exposed to a “first” plasma. The ordinals are used for descriptive purposes when referring to the Figures.

In some embodiments, the substrate 102 is exposed to the silicon-containing precursor at operation 12, followed by exposure to the nitrogen-containing reactant at operation 14, followed by exposure to the first plasma including one or more of nitrogen (N₂) or hydrogen (H₂), and argon (Ar) or helium (He) at operation 16, followed by exposure to the second plasma including one or more of nitrogen (N₂), argon (Ar) helium (He), oxygen (O₂), nitrous oxide (N₂O), or carbon dioxide (CO₂) at operation 18.

In some embodiments, exposing the substrate 102 to the silicon-containing precursor at operation 12 and the nitrogen-containing reactant at operation 14 comprises a thermal process. Stated differently, exposing the substrate 102 to the silicon-containing precursor at operation 12 and the nitrogen-containing reactant at operation 14 is performed without the use of plasma. The method 10 comprises a plasma-enhanced atomic layer deposition (PEALD) process, and in accordance with one or more embodiments, the substrate 102 is exposed to a plasma (e.g., the first plasma) beginning at operation 16. The PEALD process is a spatial PEALD process or a temporal PEALD process. In some embodiments, the PEALD process is a spatial PEALD process. In some embodiments, the PEALD process is a temporal PEALD process.

As used herein, “exposing the substrate to a first plasma,” e.g., operation 16, may be interchangeably referred to as a “first plasma exposure,” and “exposing the substrate to a second plasma,” e.g., operation 18, may be interchangeably referred to as a “second plasma exposure.”

The method 10 continues to decision point 19. At decision point 19, the substrate 102 is evaluated to determine whether or not the silicon-containing film 200 has reached a predetermined thickness or a predetermined number of cycles have been performed. As used herein, each “cycle” refers to each iteration in which the method 10 is performed to deposit the silicon-containing film 200 to a predetermined thickness. If the conditions are met e.g., the answer to decision point 19 is “YES,” the method 10 continues to operation 20 for further processing. The skilled artisan will appreciate that operation 20 can include one or more subsequent operations to form a device, such as device 100 as described herein, which can be performed without undue experimentation. If the conditions are not met, e.g., the answer to decision point 19 is “NO,” the method 10 optionally returns to operation 11, or operation 12.

In one or more embodiments, the method 10 comprises, consists essentially of, or consists of operation 11, operation 12, operation 13, operation 14, operation 15, operation 16, operation 17, operation 18, decision point 19, and operation 20.

One or more embodiments of the method 10 comprise repeating one or more operations of the method to deposit the silicon-containing film 200 to a predetermined thickness.

In one or more embodiments, operation 12, optional operation 13, operation 14, optional operation 15, operation 16, optional operation 17, and operation 18 defines a first process cycle. In one or more embodiments, the first process cycle is repeated to deposit the silicon-containing film 200 to a predetermined thickness.

In one or more embodiments, operation 12, optional operation 13, operation 14, optional operation 15, operation 16, and optional operation 17 defines a second process cycle. In one or more embodiments, the second process cycle is repeated to deposit the silicon-containing film 200 to a predetermined thickness. In one or more specific embodiments, the second process cycle is repeated to deposit the silicon-containing film 200 to a predetermined thickness, then operation 18 is performed once the predetermined thickness is reached. In one or more specific embodiments, the second process cycle is repeated to deposit the silicon-containing film 200 to a predetermined thickness, then operation 18 is performed once the predetermined thickness is reached, and operation 18 can be repeated a predetermined number of times. Stated differently, the second process cycle can be repeated to deposit the silicon-containing film 200 to the predetermined thickness, followed by operation 18, and the collective process of the second process cycle plus operation 18 can be repeated a predetermined number of times.

Some embodiments advantageously provide the ability to control the composition of the silicon-containing film 200 in accordance with the methods described herein. Some embodiments advantageously provide the ability to control the thickness of the silicon-containing film 200 to Angstrom-level accuracy in accordance with the methods described herein. Some embodiments advantageously provide the ability to control the step coverage, e.g., less than 100%, 100%, or greater than 100% of the silicon-containing film 200 in accordance with the methods described herein.

The silicon-containing film 200 comprises one or more of silicon nitride (SiN), silicon oxide (SiO), silicon carbonitride (SiCN), silicon oxycarbide (SiOC), or silicon carboxynitride (SiCON).

The silicon-containing precursor may be any suitable precursor that includes silicon. In some embodiments, the silicon-containing precursor includes, but is not limited to, one or more of a silane (SiₓH_{y}), a chlorosilane (SiₓH_{y}Cl_{z}), or an iodosilane (SiₓH_{y}I_{z}). In some embodiments, the silicon-containing precursor includes one or more of silane (SiH₄), disilane (Si₂H₆), chlorosilane (H₃SiCl), dichlorosilane (H₂SiCl₂), trichlorosilane (HSiCl₃), tetrachlorosilane (SiCl₄), iodosilane (H₃ISi), diiodosilane (H₂I₂Si), triiodosilane (HI₃Si), or tetraiodosilane (I₄Si). In some embodiments, the silicon-containing precursor includes bis(diethylamino) silane (BDEAS). In some embodiments, the silicon-containing precursor comprises dichlorosilane (H₂SiCl₂).

The nitrogen-containing reactant may be any suitable reactant that includes nitrogen. In some embodiments, the nitrogen-containing reactant is a reactant that includes nitrogen and carbon. In some embodiments, the nitrogen-containing reactant includes, but is not limited to, one or more of nitrogen (N₂), ammonia (NH₃), a substituted alkylamine, or an unsubstituted alkylamine. In some embodiments, the nitrogen-containing reactant comprises one or more of ammonia (NH₃) or ethylenediamine. In some embodiments, the nitrogen-containing reactant comprises ammonia (NH₃). In some embodiments, the nitrogen-containing reactant comprises ethylenediamine.

In one or more embodiments, the first plasma includes one or more of nitrogen (N₂) or hydrogen (H₂), and one or more of argon (Ar) or helium (He). In one or more embodiments, the first plasma comprises nitrogen (N₂), hydrogen (H₂), argon (Ar), and helium (He). In one or more embodiments, the first plasma consists essentially of nitrogen (N₂), hydrogen (H₂), argon (Ar), and helium (He). In one or more embodiments, the first plasma consists of nitrogen (N₂), hydrogen (H₂), argon (Ar), and helium (He).

In one or more embodiments, the first plasma comprises nitrogen (N₂) and argon (Ar). In one or more embodiments, the first plasma consists essentially of nitrogen (N₂) and argon (Ar). In one or more embodiments, the first plasma consists of nitrogen (N₂) and argon (Ar).

In one or more embodiments, the first plasma comprises nitrogen (N₂) and helium (He). In one or more embodiments, the first plasma consists essentially of nitrogen (N₂) and helium (He). In one or more embodiments, the first plasma consists of nitrogen (N₂) and helium (He).

In one or more embodiments, the first plasma comprises nitrogen (N₂) and a mixture of argon (Ar) and helium (He). In one or more embodiments, the first plasma consists essentially of nitrogen (N₂) and a mixture of argon (Ar) and helium (He). In one or more embodiments, the first plasma consists of nitrogen (N₂) and a mixture of argon (Ar) and helium (He).

In one or more embodiments, the first plasma comprises hydrogen (H₂) and argon (Ar). In one or more embodiments, the first plasma consists essentially of hydrogen (H₂) and argon (Ar). In one or more embodiments, the first plasma consists of hydrogen (H₂) and argon (Ar).

In one or more embodiments, the first plasma comprises hydrogen (H₂) and helium (He). In one or more embodiments, the first plasma consists essentially of hydrogen (H₂) and helium (He). In one or more embodiments, the first plasma consists of hydrogen (H₂) and helium (He).

In one or more embodiments, the first plasma comprises hydrogen (H₂) and a mixture of argon (Ar) and helium (He). In one or more embodiments, the first plasma consists essentially of hydrogen (H₂) and a mixture of argon (Ar) and helium (He). In one or more embodiments, the first plasma consists of hydrogen (H₂) and a mixture of argon (Ar) and helium (He).

Without intending to be bound by theory, it is thought that the first plasma comprising nitrogen (N₂) and one or more of argon (Ar) or helium (He) densifies the silicon-containing film by cross-linking the bonding between the silicon atoms from the silicon-containing precursor and reactive nitrogen species from the first plasma comprising nitrogen (N₂), e.g. nitrogen radicals and nitrogen ions. In one or more embodiments, the substrate 102 is purged after the first plasma exposure, prior to the second plasma exposure.

In one or more embodiments, the second plasma includes one or more of nitrogen (N₂), argon (Ar), helium (He), oxygen (O₂), nitrous oxide (N₂O), or carbon dioxide (CO₂). In one or more embodiments, the second plasma comprises nitrogen (N₂), argon (Ar), helium (He), oxygen (O₂), nitrous oxide (N₂O), and carbon dioxide (CO₂). In one or more embodiments, the second plasma consists essentially of nitrogen (N₂), argon (Ar), helium (He), oxygen (O₂), nitrous oxide (N₂O), and carbon dioxide (CO₂). In one or more embodiments, the second plasma consists of nitrogen (N₂), argon (Ar), helium (He), oxygen (O₂), nitrous oxide (N₂O), and carbon dioxide (CO₂).

In one or more embodiments, the second plasma comprises nitrogen (N₂) and argon (Ar). In one or more embodiments, the second plasma consists essentially of nitrogen (N₂) and argon (Ar). In one or more embodiments, the second plasma consists of nitrogen (N₂) and argon (Ar).

In one or more embodiments, the second plasma comprises nitrogen (N₂) and helium (He). In one or more embodiments, the second plasma consists essentially of nitrogen (N₂) and helium (He). In one or more embodiments, the second plasma consists of nitrogen (N₂) and helium (He).

In one or more embodiments, the second plasma comprises nitrogen (N₂) and a mixture of argon (Ar) and helium (He). In one or more embodiments, the second plasma consists essentially of nitrogen (N₂) and a mixture of argon (Ar) and helium (He). In one or more embodiments, the second plasma consists of nitrogen (N₂) and a mixture of argon (Ar) and helium (He).

In one or more embodiments, the second plasma comprises one or more of oxygen (O₂), nitrous oxide (N₂O), or carbon dioxide (CO₂). In one or more embodiments, the second plasma comprises oxygen (O₂), nitrous oxide (N₂O), and carbon dioxide (CO₂). In one or more embodiments, the second plasma consists essentially of oxygen (O₂), nitrous oxide (N₂O), and carbon dioxide (CO₂). In one or more embodiments, the second plasma consists of oxygen (O₂), nitrous oxide (N₂O), and carbon dioxide (CO₂).

In one or more embodiments, the second plasma comprises, consists essentially of, or consists of oxygen (O₂). In one or more embodiments, the second plasma comprises, consists essentially of, or consists of nitrous oxide (N₂O). In one or more embodiments, the second plasma comprises, consists essentially of, or consists of carbon dioxide (CO₂).

Without intending to be bound by theory, it is thought that the second plasma including one or more of nitrogen (N₂), argon (Ar), helium (He), oxygen (O₂), nitrous oxide (N₂O), or carbon dioxide (CO₂) removes surface atoms from the silicon-containing precursor, such as, for example, hydrogen atoms and/or chlorine atoms.

It has been advantageously found that exposing each location on the substrate surface to the same amount of time to the first plasma including one or more of nitrogen (N₂) or hydrogen (H₂), and one or more of argon (Ar) or helium (He), and the second plasma including one or more of nitrogen (N₂), argon (Ar), helium (He), oxygen (O₂), nitrous oxide (N₂O), or carbon dioxide (CO₂), the thickness non-uniformity of the silicon-containing film is improved compared to current PEALD approaches.

The first plasma and the second plasma may be independently generated by any suitable plasma source. In one or more embodiments, a remote plasma source, an inductively coupled plasma (ICP) source, a capacitively coupled plasma (CCP) source, or a microwave plasma source may be used to generate the first plasma and/or the second plasma. The skilled artisan will appreciate that any remote plasma source, inductively coupled plasma (ICP) source, capacitively coupled plasma source (CCP) source, or microwave plasma source that is suitable for generating the first plasma and/or the second plasma may be implemented for the disclosed methods.

During the deposition operation, an additional power source, such as a bias power source, may be engaged and coupled to provide a bias to the plasma (e.g., the first plasma and/or the second plasma) generated above the substrate 102. The bias may draw plasma particles from the first plasma and/or the second plasma to the substrate 102. The bias power applied may be relatively low to limit damage to a device including the silicon-containing film 200, e.g., device 100. Accordingly, in some embodiments a bias power source may deliver a plasma power of less than or about 1,000 W and may deliver a power of less than or about 750 W, less than or about 600 W, less than or about 500 W, less than or about 400 W, or less. Additionally, by adjusting the plasma source power and the bias power applied, densification of the deposited silicon-containing film may occur during the deposition operation. In one or more embodiments, both the plasma source power and the bias power may be applied.

In specific embodiments, the method 10 comprises optionally pre-treating the substrate at operation 11, exposing the substrate 102 to a silicon-containing precursor comprising dichlorosilane (H₂SiCl₂) at operation 12, optionally purging the substrate 102 at operation 13, exposing the substrate 102 to a nitrogen-containing reactant comprising ammonia (NH₃) at operation 14, optionally purging the substrate 102 at operation 15, exposing the substrate 102 to the first plasma comprising nitrogen (N₂) and argon (Ar) at operation 16, optionally purging the substrate 102 at operation 17, exposing the substrate 102 to the second plasma comprising nitrogen (N₂) and helium (He) at operation 18, and evaluating the substrate 102 at decision point 19 to determine whether or not the silicon-containing film has reached a predetermined thickness or a predetermined number of cycles have been performed. In specific embodiments, the silicon-containing film comprises silicon nitride (SiN).

In specific embodiments, exposing the substrate 102 to the first plasma comprising nitrogen (N₂) and argon (Ar) at operation 16 advantageously provides the ability to control the thickness conformality of the deposited silicon-containing film (e.g., the silicon nitride (SiN) film) to Angstrom-level accuracy.

In specific embodiments, exposing the substrate 102 to the second plasma comprising nitrogen (N₂) and helium (He) at operation 18 advantageously provides the ability to control the composition of the deposited silicon-containing film (e.g., the silicon nitride (SiN) film). In specific embodiments, exposing the substrate 102 to the second plasma comprising nitrogen (N₂) and helium (He) at operation 18 advantageously makes the composition of the deposited silicon-containing film (e.g., the silicon nitride (SiN) film) uniform across the entirety of the film. As used herein, a film that has a “uniform” composition means that the composition of the film has less than about 10%, 5%, 2%, 1% or 0.5% variation in the entirety of the film.

In one or more embodiments, the deposited silicon-containing film (e.g., the silicon nitride (SiN) film) has a uniform composition on the top surface 103, along the two sidewalls 164, and on the bottom surface 161 as a result of exposing the substrate 102 to the second plasma comprising nitrogen (N₂) and helium (He) at operation 18.

It has been found that exposing the substrate 102 to the second plasma comprising nitrogen (N₂) and helium (He) at operation 18 with a bias power source engaged and coupled to the plasma source to provide a bias to the second plasma advantageously makes the composition of the deposited silicon-containing film (e.g., the silicon nitride (SiN) film) uniform across the entirety of the film.

It has been found that exposing the substrate 102 to the second plasma comprising nitrogen (N₂) and helium (He) at operation 18 where the second plasma is a radical-rich plasma advantageously makes the composition of the deposited silicon-containing film (e.g., the silicon nitride (SiN) film) uniform across the entirety film.

It has been found that exposing the substrate 102 to the second plasma comprising nitrogen (N₂) and helium (He) at operation 18 at a low process pressure, such as in a range of from 0.1 Torr to 1 Torr, advantageously makes the composition of the deposited silicon-containing film (e.g., the silicon nitride (SiN) film) uniform across the entirety of the film.

In specific embodiments, exposing the substrate 102 to the second plasma comprising nitrogen (N₂) and helium (He) at operation 18 advantageously provides the ability to remove hydrogen atoms and chlorine atoms from the deposited silicon-containing film (e.g., the silicon nitride (SiN) film), such as from the bottom surface 161 of the at least one feature 150.

In specific embodiments, the method 10 comprises optionally pre-treating the substrate at operation 11, exposing the substrate 102 to a silicon-containing precursor comprising dichlorosilane (H₂SiCl₂) at operation 12, optionally purging the substrate 102 at operation 13, exposing the substrate 102 to a nitrogen-containing reactant comprising ethylenediamine at operation 14, optionally purging the substrate 102 at operation 15, exposing the substrate 102 to the first plasma comprising hydrogen (H₂) and argon (Ar) at operation 16, optionally purging the substrate 102 at operation 17, exposing the substrate 102 to the second plasma comprising one or more of oxygen (O₂), nitrous oxide (N₂O), or carbon dioxide (CO₂) at operation 18, and evaluating the substrate 102 at decision point 19 to determine whether or not the silicon-containing film has reached a predetermined thickness or a predetermined number of cycles have been performed. In specific embodiments, the silicon-containing film comprises silicon carboxynitride (SiCON).

In specific embodiments, exposing the substrate 102 to the first plasma comprising hydrogen (H₂) and argon (Ar) at operation 16 advantageously provides the ability to control the thickness conformality of the deposited silicon-containing film (e.g., the silicon carbonitride (SiCN) film) to Angstrom-level accuracy.

In specific embodiments, exposing the substrate 102 to the second plasma comprising plasma comprising one or more of oxygen (O₂), nitrous oxide (N₂O), or carbon dioxide (CO₂) at operation 18 advantageously provides the ability to control the composition of the deposited silicon-containing film. In specific embodiments, exposing the substrate 102 to the second plasma comprising plasma comprising one or more of oxygen (O₂), nitrous oxide (N₂O), or carbon dioxide (CO₂) at operation 18 oxidizes the silicon carbonitride (SiCN) film to form a silicon carboxynitride (SiCON) film.

In specific embodiments, exposing the substrate 102 to the second plasma comprising one or more of oxygen (O₂), nitrous oxide (N₂O), or carbon dioxide (CO₂) at operation 18 is advantageously configured to make the composition of the deposited silicon-containing film (e.g., silicon carboxynitride (SiCON) film) uniform across the entirety of the film. Stated differently, in one or more embodiments, the deposited silicon-containing film (e.g., the silicon carboxynitride (SiCON) film) has a uniform composition on the top surface 103, along the two sidewalls 164, and on the bottom surface 161 as a result of exposing the substrate 102 to the second plasma comprising nitrogen (N₂) and helium (He) at operation 18.

It has been found that exposing the substrate 102 to the second plasma comprising one or more of oxygen (O₂), nitrous oxide (N₂O), or carbon dioxide (CO₂) at operation 18 with a bias power source engaged and coupled to the plasma source to provide a bias to the second plasma advantageously makes the composition of the deposited silicon-containing film (e.g., the silicon carboxynitride (SiCON) film) uniform across the entirety of the film. It has been found that exposing the substrate 102 to the second plasma comprising one or more of oxygen (O₂), nitrous oxide (N₂O), or carbon dioxide (CO₂) at operation 18 where the second plasma is a radical-rich plasma advantageously makes the composition of the deposited silicon-containing film (e.g., the silicon carboxynitride (SiCON) film) uniform across the entirety of the film. It has been found that exposing the substrate 102 to the second plasma comprising one or more of oxygen (O₂), nitrous oxide (N₂O), or carbon dioxide (CO₂) at operation 18 at a low process pressure, such as in a range of from 0.1 Torr to 1 Torr, advantageously makes the composition of the deposited silicon-containing film (e.g., the silicon carboxynitride (SiCON) film) uniform across the entirety of the film.

The method 10 may be performed at any suitable processing conditions, and the processing conditions may vary depending upon the application for which the silicon-containing film is formed.

In some embodiments, the method 10 is performed at relatively low temperatures. The relative low temperatures advantageously result in decreased damage to surrounding materials (e.g., dielectric materials). In some embodiments, the method 10 is performed at a temperature in the range of 20° C. to 600° C. Stated differently, “the method 10 is performed at a temperature in the range of 20° C. to 600° C.” means that the semiconductor processing system in which the method 10 is performed is maintained at a temperature in the range of 20° C. to 600° C. In some embodiments, the method 10 is performed at a temperature in the range of 100° C. to 600° C.

In some embodiments, the method 10 is performed at a pressure in a range of from 0.1 Torr to 30 Torr. Stated differently, “the method 10 is performed at a pressure in a range of from 0.1 Torr to 30 Torr” means that the semiconductor processing system in which the method 10 is performed is maintained at a pressure in a range of from 0.1 Torr to 30 Torr. In some embodiments, the method 10 is performed at a temperature in the range of 0.1 Torr to 1 Torr.

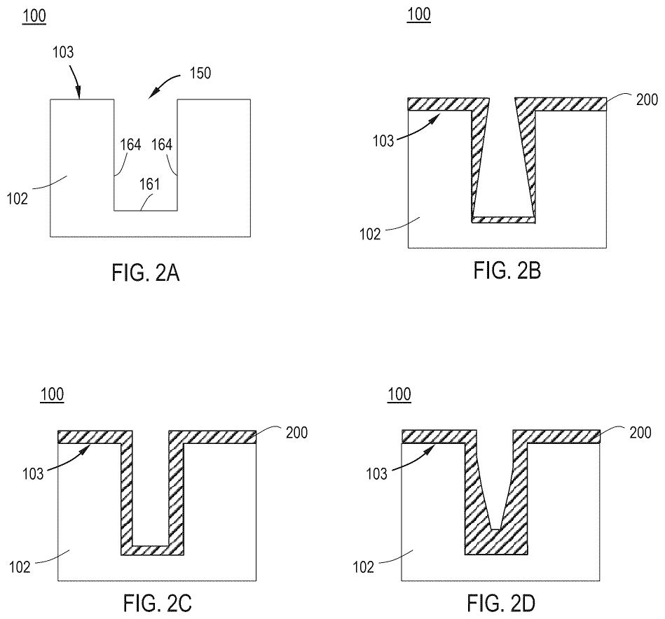

FIGS. 2A-2D also illustrate cross-sectional schematic views of a device 100 including a substrate 102 according to one or more embodiments of the disclosure. The device 100 shown in FIGS. 2A-2D is generally representative of a semiconductor device or a microelectronic device. In specific embodiments, the device 100 shown in FIGS. 2A-2D is representative of a high aspect ratio structure, e.g., in memory devices or logic devices (at less than 10 nm technology nodes), including, but not limited to, NAND, 3D-NAND, dynamic random-access memory (DRAM) cells, 3D DRAM, Fin field effect transistors (FinFET), gate-all-around (GAA) transistors, and the like.

The substrate 102 can be any suitable substrate material. In one or more embodiments, the substrate 102 comprises a semiconductor material, e.g., any metal material, silicon (Si), carbon (C), germanium (Ge), silicon germanium (SiGe), gallium arsenide (GaAs), indium phosphate (InP), indium gallium arsenide (InGaAs), indium aluminum arsenide (InAlAs), germanium (Ge), silicon germanium (SiGe), a high-K dielectric material other semiconductor materials, or any combination thereof. In one or more embodiments, the substrate 102 comprises one or more of silicon (Si), germanium (Ge), gallium (Ga), arsenic (As), indium (In), phosphorus (P), or selenium (Se). Although a few examples of materials from which the substrate 102 may be made have been provided, any material that may serve as a foundation upon which passive and active electronic devices (e.g., transistors, memories, capacitors, inductors, resistors, switches, integrated circuits, amplifiers, optoelectronic devices, or any other electronic devices) may can be utilized.

In some embodiments, the substrate 102 may include dielectric materials, for example, silicon-containing dielectric materials and/or metal oxide dielectric materials. In some embodiments, the substrate 102 may comprise one or more dielectric surfaces comprising a low-K dielectric material such as, but not limited to, silicon oxide (SiO), silicon sub-oxides, silicon nitride (SiN), silicon nitride (Si₃N₄), silicon carbide (SiC), silicon oxycarbide (SiOC), silicon carbonitride (SiCN), silicon oxynitride (SiON), or combinations thereof.

FIG. 2A illustrates the substrate 102 having a top surface 103 and including at least one feature 150 extending into the substrate 102. The at least one feature 150 has a bottom surface 161 and two sidewalls 164. In some embodiments, the bottom surface 161 comprises a metallic material. In some embodiments, the bottom surface 161 comprises a dielectric material. In some embodiments, the two sidewalls 164 comprise a dielectric material. In some embodiments, the two sidewalls 164 comprise a metallic material.

While the at least one feature 150 is shown extending vertically into the substrate 102, the skilled artisan will appreciate that disclosure is not limited to the illustrated embodiments, and that the at least one feature 150 can extend laterally within the substrate 102. In one or more embodiments, the substrate 102 having the at least one feature 150 includes one or more vertically extending features and one or more laterally extending features.

In FIGS. 2B-2D, a silicon-containing film 200 is formed on the top surface 103, along the two sidewalls 164, and on the bottom surface 161. In FIG. 2B, the silicon-containing film 200 is not conformally deposited on the top surface 103, along the two sidewalls 164, and on the bottom surface 161. That is, the silicon-containing film 200 as shown in FIG. 2B varies in thickness by greater than about 5%, 2%, 1% or 0.5%, on the top surface 103, along the two sidewalls 164, and on the bottom surface 161.

In FIG. 2B, the silicon-containing film 200 has a thickness on the top surface 103 that is greater than a thickness of the silicon-containing film along the two sidewalls 164. In one or more embodiments, the thickness of the silicon-containing film 200 on the top surface 103 and the thickness of the silicon-containing film along the two sidewalls 164 varies by greater than about 5%, 2%, 1% or 0.5%.

In one or more embodiments, the thickness of the silicon-containing film along the two sidewalls 164 defines a gradient thickness that increases from the top surface 103 towards the bottom surface 161.

In FIG. 2B, the silicon-containing film 200 has a thickness on the top surface 103 that is greater than a thickness of the silicon-containing film on the bottom surface 161. In one or more embodiments, the thickness of the silicon-containing film 200 on the top surface 103 and the thickness of the silicon-containing film on the bottom surface 161 varies by greater than about 5%, 2%, 1% or 0.5%. FIG. 2B also illustrates an example of the silicon-containing film 200 having a step coverage of less than 100%.

In FIG. 2C, the silicon-containing film 200 is shown as conformally deposited on the top surface 103, along the two sidewalls 164, and on the bottom surface 161. Exposing the substrate 102 to the first plasma comprising one or more of nitrogen (N₂) or hydrogen (H₂), and argon (Ar) at operation 16 advantageously provides the ability to control the thickness conformality of the deposited silicon-containing film 200 to Angstrom-level accuracy. That is, the first plasma exposure advantageously improves the thickness conformality from FIG. 2B (non-conformal) to make the silicon-containing film 200 conformal, as shown in FIG. 2C. Accordingly, FIG. 2C is an example of the silicon-containing film 200 having a step coverage of 100%.

In FIG. 2D, the silicon-containing film 200 is shown after the second plasma exposure. In one or more embodiments, exposing the substrate 102 to the second plasma including one or more of nitrogen (N₂), argon (Ar), helium (He), oxygen (O₂), nitrous oxide (N₂O), or carbon dioxide (CO₂) at operation 18 is advantageously makes the composition of the deposited silicon-containing film 200 uniform across the entirety of the film. Stated differently, in one or more embodiments, the deposited silicon-containing film 200 has a uniform composition on the top surface 103, along the two sidewalls 164, and on the bottom surface 161 as a result of the second plasma exposure. FIG. 2D also illustrates an example of the silicon-containing film 200 having a step coverage of greater than 100%. In one or more embodiments, the silicon-containing film 200 is deposited to fill the at least one feature 150. In one or more embodiments where the silicon-containing film 200 is deposited to fill the at least one feature 150, the silicon-containing film 200 is free of seams and/or voids.

It has been found that engaging and coupling a bias power source to the plasma source to provide a bias to the second plasma during the second plasma exposure advantageously makes the composition of the deposited silicon-containing film 200 uniform across the entirety of the film. It has been advantageously found that where the second plasma is a radical-rich plasma, the radical-rich plasma makes the composition of the deposited silicon-containing film 200 uniform across the entirety of the film. It has been found that performing the second plasma exposure at a low process pressure, such as in a range of from 0.1 Torr to 1 Torr, advantageously makes the composition of the deposited silicon-containing film 200 across the entirety of the film.

In accordance with the method 10, at decision point 19, the substrate 102 is evaluated to determine whether or not the silicon-containing film 200 has reached a predetermined thickness or a predetermined number of cycles have been performed. In some embodiments, the silicon-containing film 200 has a thickness in a range of from about 0.5 nm to about 30 nm.

In one or more embodiments, the method 10 is part of a gap fill process. The method 10 may be utilized with any device nodes, but may be particularly advantageous in device nodes of about 25 nm or less, for example about 5 nm to about 25 nm. In some embodiments, a silicon-containing film 200 is deposited on a dielectric surface with one or more high aspect ratio structures, including vertically extending features and/or laterally extending features, and the silicon-containing film 200 in the gap features forms interconnects through which current flows. It will be appreciated by the skilled artisan that the method 10 that is part of a gap fill process can include one or more subsequent operations after forming the silicon-containing film 200, such as, for example, filling the gap with a conductive material, to form an interconnect, and that the one or more subsequent operations can be performed without undue experimentation.

The methods described herein may be performed in any suitable processing system that includes a PEALD processing chamber. In some embodiments, a suitable processing system comprises: a central transfer station comprising a robot configured to move a substrate or a plurality of substrates, a plurality of process stations, and a controller connected to the central transfer station and the plurality of process stations. In some embodiments, each process station is connected to the central transfer station and provides a processing region separated from processing regions of adjacent process stations. In some embodiments, the plurality of process stations comprises a plasma-enhanced atomic layer deposition (PEALD) chamber. In some embodiments, the controller is configured to activate the robot to move the substrate between process stations, and to control a processing method, such as method 10, and form a silicon-containing film, e.g., the silicon-containing film 200 on the substrate.

In some embodiments, one or more operations of the method 10 are performed in situ. In some embodiments, each operations of the method 10 is performed in situ. In some embodiments, one or more operations of the method 10 are performed ex situ.

One or more embodiments of the disclosure are directed to a non-transitory computer readable medium including instructions, that, when executed by a controller of a processing system, cause the processing system to perform the operations of method 10.

Although the disclosure herein has been described with reference to particular embodiments, those skilled in the art will understand that the embodiments described are merely illustrative of the principles and applications of the present disclosure. It will be apparent to those skilled in the art that various modifications and variations can be made to the method and apparatus of the present disclosure without departing from the spirit and scope of the disclosure. Thus, the present disclosure can include modifications and variations that are within the scope of the appended claims and their equivalents.

What is claimed is:

1. A method of depositing a silicon-containing film, the method comprising:
exposing a substrate in a processing system to a silicon-containing precursor;
exposing the substrate to a nitrogen-containing reactant;
exposing the substrate to a first plasma including one or more of nitrogen (N₂) or hydrogen (H₂), and one or more of argon (Ar) or helium (He); and
exposing the substrate to a second plasma including one or more of nitrogen (N₂), argon (Ar), helium (He), oxygen (O₂), nitrous oxide (N₂O), or carbon dioxide (CO₂).

2. The method of claim 1, comprising repeating one or more operations of the method to deposit the silicon-containing film to a predetermined thickness.

3. The method of claim 1, wherein the method comprises a plasma-enhanced atomic layer deposition (PEALD) process, and exposing the substrate to the silicon-containing precursor the nitrogen-containing reactant is performed without the use of plasma.

4. The method of claim 3, wherein the PEALD process is a spatial PEALD process or a temporal PEALD process.

5. The method of claim 3, wherein the nitrogen-containing reactant comprises one or more of ammonia (NH₃) or ethylenediamine.

6. The method of claim 1, wherein each of the first plasma and the second plasma is independently generated by a plasma source comprising one or more of a remote plasma source, an inductively coupled plasma (ICP) source, a capacitively coupled plasma (CCP) source, or a microwave plasma source.

7. The method of claim 6, wherein each of the first plasma and the second plasma independently comprises a microwave plasma generated by the microwave plasma source.

8. The method of claim 6, wherein the first plasma comprises nitrogen (N₂) and one or more of argon (Ar) or helium (He).

9. The method of claim 6, wherein the first plasma comprises hydrogen (H₂) and one or more of argon (Ar) or helium (He).

10. The method of claim 6, wherein the second plasma comprises nitrogen (N₂) and one or more of argon (Ar) or helium (He).

11. The method of claim 10, wherein a bias is provided to the second plasma.

12. The method of claim 6, wherein the second plasma comprises one or more of oxygen (O₂), nitrous oxide (N₂O), or carbon dioxide (CO₂).

13. The method of claim 12, wherein a bias is provided to the second plasma.

14. The method of claim 1, wherein the silicon-containing film comprises one or more of silicon nitride (SiN), silicon oxide (SiO), silicon carbonitride (SiCN), silicon oxycarbide (SiOC), or silicon carboxynitride (SiCON).

15. The method of claim 1, wherein the substrate comprises at least one feature having a bottom surface and two sidewalls.

16. The method of claim 15, wherein the at least one feature has an aspect ratio in a range of 1:1 to 100:1.

17. The method of claim 1, performed at a temperature in a range of from 100° C. to 600° C.

18. The method of claim 1, performed at a pressure in a range of from 0.1 Torr to 30 Torr.

19. A method of depositing a silicon-containing film, the method comprising:
exposing a substrate in a processing system to a silicon-containing precursor;
exposing the substrate to ammonia (NH₃);
exposing the substrate to a first plasma including nitrogen (N₂) and argon (Ar); and
exposing the substrate to a second plasma including nitrogen (N₂) and helium (He), wherein the method comprises a plasma-enhanced atomic layer deposition (PEALD) process, and exposing the substrate to the silicon-containing precursor and the ammonia (NH₃) is performed without the use of plasma.

20. A method of depositing a silicon-containing film, the method comprising:
exposing a substrate in a processing system to a silicon-containing precursor;
exposing the substrate to ethylenediamine;
exposing the substrate to a first plasma including hydrogen (H₂) and argon (Ar); and
exposing the substrate to a second plasma including one or more of oxygen (O₂), nitrous oxide (N₂O), or carbon dioxide (CO₂), wherein the method comprises a plasma-enhanced atomic layer deposition (PEALD) process, and exposing the substrate to the silicon-containing precursor and the ethylenediamine is performed without the use of plasma.
